(19) United States
(12) Patent Application Publication
(10) Pub. No.: US 2026/0362642 A1
(43) Pub. Date: Nov. 12, 2026

(54) MANIFOLD ASSEMBLY AND DATA CENTER LIQUID COOLING SYSTEM

(71) Applicant: AAC ACOUSTIC TECHNOLOGIES (SHENZHEN) CO., LTD., Shenzhen (CN)

(72) Inventors: Zengjie Lu, Shenzhen (CN); Fangwei Wei, Shenzhen (CN); Xinghua Ning, Shenzhen (CN); Shaoqiang Chen, Shenzhen (CN); Kaiwen Gong, Shenzhen (CN)

(21) Appl. No.: 19/333,368

(22) Filed: Sep. 19, 2025

Related U.S. Application Data
(63) Continuation of application No. PCT/CN2025/093494, filed on May 8, 2025.

(51) Int. Cl. H05K 7/20

(52) U.S. Cl. CPC H05K 7/20272; H05K 7/20763

(57) ABSTRACT

Provided are a manifold assembly and a data center liquid cooling system. The manifold assembly includes a liquid supply manifold having a first liquid supply port and multiple second liquid supply ports, and a liquid return manifold including first and second liquid return tubes. The first liquid supply port and the second liquid supply ports are connected to a coolant supply system and devices to be cooled, respectively. The flow direction of the first liquid return tube is the same as that of the liquid supply manifold and opposite to that of the second liquid return tube. The first liquid return tube has multiple first liquid return ports connected to the devices. The second liquid return tube has a second liquid return port. The lengths of all flow paths are equal. The manifold assembly ensures uniform coolant distribution, thereby improving system heat dissipation efficiency and system stability.

### CROSS-REFERENCE TO RELATED APPLICATIONS

This application is a continuation of International Application No. PCT/CN2025/093494, filed May 8, 2025, the entire contents of which are incorporated herein by reference.

### TECHNICAL FIELD

The present application relates to the field of liquid cooling systems, in particular to a manifold assembly and a data center liquid cooling system.

### BACKGROUND

In modern data centers and high-performance computing environments, liquid cooling systems are widely adopted as an efficient thermal management solution for cooling high-heat-generating electronic devices such as servers and storage equipment. Compared to conventional air-cooling systems, liquid cooling systems offer superior heat dissipation efficiency and lower energy consumption, making them particularly suitable for handling the intensive heat generated during the processing of large amounts of data and the execution of complex computational tasks. However, in practical applications, the issue of uneven coolant distribution is often overlooked, despite its critical impact on equipment performance. Conventional liquid cooling systems typically employ a reverse-return piping structure for supply and return coolant manifolds, which can lead to uneven coolant distribution. This may result in some devices receiving insufficient coolant while others may experience overcooling, ultimately compromising cooling effectiveness. To compensate for uneven coolant distribution, liquid cooling systems often require higher pump power to ensure adequate cooling across all areas, leading to unnecessary energy consumption.

Therefore, it is necessary to provide a manifold assembly with uniform coolant distribution and a data center liquid cooling system.

### SUMMARY

An object of the present application is to provide a manifold assembly and a data center liquid cooling system to address the technical issue of uneven coolant distribution in the related art.

The technical solution of the present application is as follows:

In the first aspect, the present application provides a manifold assembly, including:
a liquid supply manifold having a first liquid supply port and a plurality of second liquid supply ports, wherein the first liquid supply port and the second liquid supply ports are sequentially spaced apart along a flow direction of the liquid supply manifold, the first liquid supply port is connected to a coolant supply system, and the second liquid supply ports are connected to corresponding devices to be cooled; and
a liquid return manifold including a first liquid return tube and a second liquid return tube that are parallel to each other and connected at one end, wherein a flow direction of the first liquid return tube is the same as the flow direction of the liquid supply manifold and opposite to a flow direction of the second liquid return tube; the first liquid return tube is provided with a plurality of first liquid return ports arranged in sequence along the flow direction of the first liquid return tube; the first liquid return ports are connected to the corresponding devices to be cooled, and the second liquid return tube is provided a second liquid return port, which is connected to the coolant recovery system;
wherein lengths of supply and return liquid flow paths of all the devices to be cooled are equal, and the length of each of the supply and return liquid flow path of the device to cooled is a sum of a flow path length between the first liquid supply port and the corresponding second liquid supply port of the device to cooled and a flow path length between the corresponding first liquid return port of the device to cooled and the second liquid return port.

As an improvement, the second liquid return tube is fixed to the first liquid return tube.

As an improvement, the flow direction of the liquid supply manifold is upward.

As an improvement, the manifold assembly further includes a first exhaust valve and a second exhaust valve, wherein the first exhaust valve is disposed at an upper end of the liquid supply manifold, and the second exhaust valve is disposed at an upper end of the liquid return manifold and is in communication with the first liquid return tube and the second liquid return tube.

As an improvement, a length of the liquid supply manifold, a length of the first liquid return tube, and a length of the second liquid return tube are equal.

As an improvement, a lumen of the liquid supply manifold, a lumen of the first liquid return tube, and a lumen of the second liquid return tube have identical cross-sectional shapes, with equal cross-sectional areas.

As an improvement, the cross-sectional shapes of the lumens of the liquid supply manifold, the first liquid return tube, and the second liquid return tube are square.

As an improvement, the second liquid supply ports are uniformly spaced, the first liquid return ports are uniformly spaced, and a distance between two adjacent second liquid supply ports is equal to a distance between two adjacent first liquid return ports.

As an improvement, the first liquid supply port and the second liquid return port are located at the same height position, and the second liquid supply port and the first liquid return port connected to the same device to be cooled are located at the same height position.

In the second aspect, the present application provides a data center liquid cooling system including any one of the above manifold assemblies.

The beneficial effects of the present application are as follows: the manifold assembly and the data center liquid cooling system of the present application include a supply manifold and a liquid return manifold. The liquid return manifold includes a first liquid return tube and second liquid return tubes. Coolant from the coolant supply system enters the liquid supply manifold through the first liquid supply port, then flows through the second liquid supply port into the device to be cooled such as servers, The coolant, which has absorbed heat from the device to be cooled, flows into the first liquid return tube through the first liquid return port, and then enters the coolant recovery system through the second liquid return ports of the second liquid return tubes. The supply and return liquid flow paths for all devices to be cooled are of equal length, enabling uniform distribution of coolant among the devices. This effectively avoids uneven flow caused by differences in flow path length, ensuring consistent cooling performance for each device and improving heat dissipation efficiency and stability of the system. Additionally, since the flow direction of the second liquid return tube is opposite to that of the liquid supply manifold, the first liquid supply port and second liquid return port can be located on the same end of the manifold assembly. This facilitates the connection between the coolant recovery system and the coolant supply system for coolant recycling, simplifying the system layout.

### BRIEF DESCRIPTION OF THE DRAWINGS

FIG. 1 is a three-dimensional structural diagram of a manifold assembly according to an embodiment of the present application.

FIG. 2 is a front view of the manifold assembly shown in FIG. 1.

FIG. 3 is a three-dimensional structural diagram of a manifold assembly according to a comparative embodiment of the present application.

### DETAILED DESCRIPTION OF THE EMBODIMENTS

The present application will be described in further detail with reference to the accompanying drawings and embodiments.

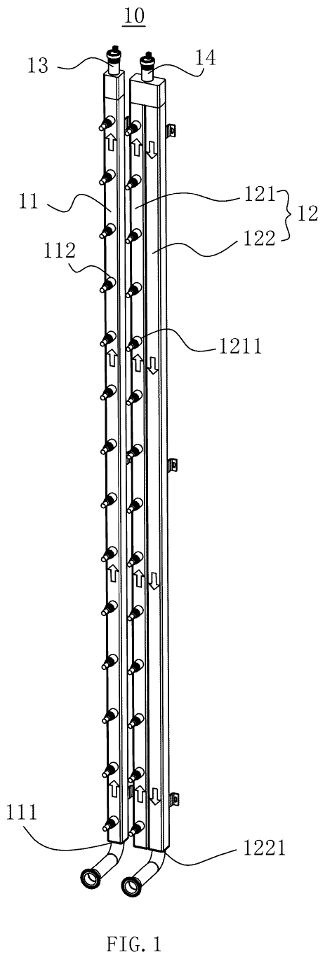

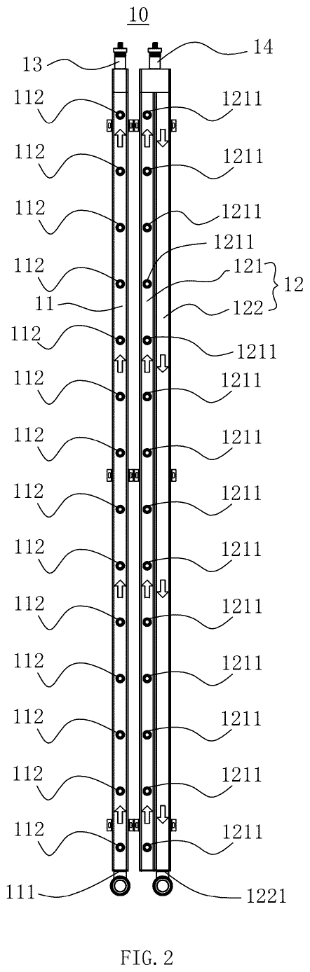

The present application provides a manifold assembly 10 including a supply manifold 11 and a liquid return manifold 12, as shown in FIGS. 1 and 2. The liquid supply manifold 11 has a first liquid supply port 111 and a plurality of second liquid supply ports 112. The first liquid supply port 111 and the second liquid supply ports 112 are sequentially spaced along a flow direction of the liquid supply manifold 11. The first liquid supply port 111 is connected to a coolant supply system, and the second liquid supply ports 112 are connected to the corresponding device to be cooled. Coolant supplied by the coolant supply system enters the liquid manifold 11 through the first liquid inlet 111. The coolant entering the liquid manifold 11 then flows into the corresponding device to be cooled through the second liquid inlets 112. The liquid return manifold 12 includes a first liquid return tube 121 and a second liquid return tube 122, which are parallel to each other, and an end of the first liquid return tube 121 is connected to an end of the second liquid return tube 122. The flow direction of the first liquid return tube 121 is the same as that of the liquid supply manifold 11, and the flow direction of the first liquid return tube 121 is opposite to that of the second liquid return tube 122. The first liquid return tube 121 has a plurality of first liquid return ports 1211, which are sequentially spaced along the flow direction of the first liquid return tube 121. Each first liquid return port 1211 is connected to a device to be cooled correspondingly. The second liquid return tube 122 has a second liquid port 1221, which is connected to the coolant recovery system. Coolant that has absorbed heat from the devices to be cooled enters the first liquid return tube 121 through the first liquid return ports 1211. The coolant flowing into the first liquid return tube 121 then flows into the second liquid return tube 122 and exits through the second liquid return port 1221 of the second liquid return tube 122 into the coolant recovery system. The lengths of the supply and return liquid flow paths of all device to be cooled are equal, and the length of each of the supply and return liquid flow paths for the device to be cooled is the sum of the length of the supply liquid flow path and the length of the return liquid flow path for the device to be cooled. The length of the supply liquid flow path for the device to be cooled is the length of the flow path between the first liquid supply port 111 and the corresponding second liquid supply port 112 of the device to be cooled. The length of the return liquid flow path for the device to be cooled is the length of the flow path between the corresponding first liquid return port 1211 of the device to be cooled and the second liquid return port 1221.

In the embodiments of the present application, the supply and return liquid flow path lengths of all devices to be cooled are equal, achieving a parallel design. This enables uniform distribution of the cooling liquid among the various devices, effectively avoiding uneven flow rates caused by differences in flow path lengths, ensuring uniform flow rates at each device node, and preventing local overheating or insufficient cooling. This ensures that each device achieves the same cooling effect, thereby improving the system's heat dissipation efficiency and system stability. Uniform flow distribution reduces additional energy consumption of the pump, significantly improving the overall energy efficiency ratio of the system. During commissioning, there is no need for additional adjustment of coolant flow rates through individual devices. The process only requires monitoring the overall temperature trend, eliminating the need for node-by-node thermal troubleshooting, thereby significantly reducing commissioning time and markedly improving debugging efficiency. Additionally, since the flow direction of the second liquid return tube 122 is opposite to that of the liquid supply manifold 11, the first liquid supply ports 111 and the second liquid return ports 1221 may be located on the same end of the manifold assembly 10, facilitating connection to the coolant recovery system and coolant supply system for coolant recycling, thereby simplifying system layout.

In some embodiments, the device to be cooled may be servers, storage devices, or other high-heat-generating electronic components, which may be configured according to actual conditions and are not further described here.

As an example, as shown in FIGS. 1 and 2, the liquid supply manifold 11 has fourteen second liquid supply ports 112, and the liquid return manifold 12 has fourteen first liquid return ports 1211. In some examples, the manifold assembly 10 may be connected to fourteen servers, each of which has an inlet tube and an outlet tube. The lengths of the inlet tubes of all servers are equal, and the lengths of the outlet tubes of all servers are equal. The second liquid supply ports 112 are connected one-to-one with the inlet tubes of the servers, and the first liquid return ports 1211 are connected one-to-one with the outlet tubes of the servers. The coolant in the liquid supply manifold 11 flows into the servers through the inlet tubes from the second liquid supply port 112. After absorbing heat from the servers, the coolant flows sequentially through the outlet tubes of the servers and the first liquid return port 1211 into the first liquid return tube 121.

In some embodiments, as shown in FIGS. 1 and 2. the second liquid return tube 122 is fixed to the first liquid return tube 121, which enhances the structural stability of the entire return liquid manifold 12, thereby effectively preventing accidental disconnection between the first liquid return tube 121 and the second liquid return tube 122 due to external forces or vibrations, ensuring the continuity and reliability of coolant return flow. Additionally, the return liquid manifold 12 may be installed as a single unit, simplifying the installation process, improving installation efficiency, and reducing the likelihood of installation errors.

In some embodiments, as the manifold assembly 10 shown in FIGS. 1 and 2, an arrow direction on the tube indicates the flow direction of the coolant within the tube. The flow direction of the liquid supply manifold 11 is upward, the flow direction of the first liquid return tube 121 is upward, and the flow direction of the second liquid return tube 122 is downward. During cooling liquid intake, the upward flow of cooling liquid within the liquid supply manifold 11 reduces bubble formation and the accumulation of bubbles at the bottom of the liquid supply manifold 11, thereby avoiding issues such as uneven flow and reduced cooling efficiency caused by bubbles. Furthermore, during liquid intake, the coolant flows upward within the liquid supply manifold 11. Along the path from the first liquid supply port 111 of the liquid supply manifold 11 to each second liquid supply port 112, the coolant needs to overcome the effects of gravity. Therefore, the gravitational resistance to coolant flow is relatively uniform between the various second liquid supply ports 112, avoiding the issue of excessive flow at the second liquid supply ports close to the first liquid supply port and insufficient flow at the second liquid supply ports far away from the first liquid supply port due to downward flow direction during liquid intake. This embodiment enables the coolant to be distributed more uniformly to each device to be cooled, reducing flow unevenness caused by gravity, improving the uniformity of cooling performance, and enhancing the overall system performance.

As an example, as shown in FIGS. 1 and 2, the first liquid supply port 111 is located at the lower end of the liquid supply manifold 11. The upper end of the first liquid return tube 121 is connected to the upper end of the second liquid return tube 122. The lower end of the first liquid return tube 121 is sealed, so the coolant entering the first liquid return tube 121 from the server can only flow upward into the second liquid return tube 122, then flow downward to the second liquid return port 1221 of the second liquid return tube 122, which is located at the lower end of the second liquid return tube 122.

In some embodiments, as shown in FIGS. 1 and 2, the manifold assembly 10 further includes a first exhaust valve 13 and a second exhaust valve 14. The first exhaust valve 13 is disposed at an upper end of the liquid supply manifold 11, allowing bubbles within the liquid supply manifold 11 to be expelled through the first exhaust valve 13. The second exhaust valve 14 is disposed at an upper end of the return liquid manifold 12, and the second exhaust valve 14 is connected to the first liquid return tube 121 and the second liquid return tube 122, allowing bubbles within the first liquid return tube 121 and the second liquid return tube 122 to be expelled through the second exhaust valve 14 to the exterior of the return liquid manifold 12.

In some embodiments, as shown in FIGS. 1 and 2, the length of the liquid supply manifold 11, the length of the first liquid return tube 121, and the length of the second liquid return tube 122 are equal, which simplifies the system structure, ensures the symmetry and consistency of the tube layout, reduces installation complexity caused by differences in tube length, and improves the stability and reliability of the system.

In some embodiments, a lumen of the liquid supply manifold 11, a lumen of the first liquid return tube 121, and a lumen of the second liquid return tube 122 have identical cross-sectional shapes. The cross-sectional area of the lumen of the liquid supply manifold 11, the cross-sectional area of the lumen of the first liquid return tube 121, and the cross-sectional area of the lumen of the second liquid return tube 122 are equal, which reduces flow unevenness and pressure loss caused by differences in tube shape and area, thereby improving the uniformity of coolant distribution and the overall performance of the system.

In some embodiments, the cross-sectional shapes of the liquid supply manifold 11, the first liquid return tube 121, and the second liquid return tube 122 are square, which improves the efficiency of coolant delivery and reduces flow resistance. Additionally, square-cross-section tubes can better adapt to space-constrained environments such as data center racks, improving space utilization.

In some embodiments, as shown in FIGS. 1 and 2, all second liquid supply ports 112 are uniformly spaced along the flow direction of the liquid supply manifold 11, all first liquid return ports 1211 are uniformly spaced along the flow direction of the first liquid return tube 121, and the distance between two adjacent second liquid supply ports 112 is equal to the distance between two adjacent first liquid return ports 1211. This ensures uniform distribution of coolant among all devices to be cooled, optimizes the coolant flow path, and improves the uniformity of cooling performance and the overall system performance.

In some embodiments, as shown in FIGS. 1 and 2, the first liquid inlet 111 and the second return liquid outlet 1221 are located at the same height position, and the second liquid inlet 112 and the first return liquid outlet 1211 that are connected to the same device to be cooled are located at the same height position, thereby avoiding flow differences caused by inconsistent positions of the second liquid inlet 112 and the first return liquid outlet 1211 corresponding to the device to cooled.

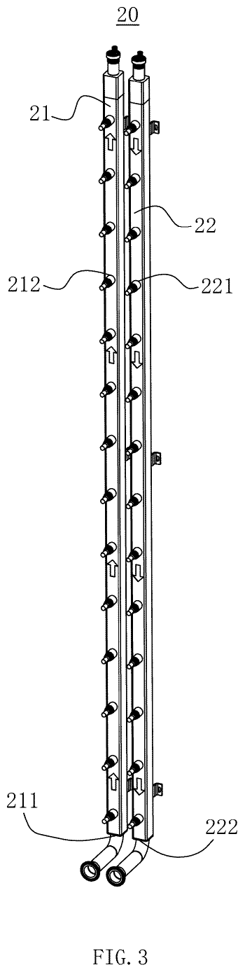

In a comparative embodiment shown in FIG. 3, the manifold assembly 20 has a reverse-return structure. As shown in FIG. 3, the manifold assembly 20 includes a liquid supply manifold 21 and a liquid return manifold 22, with the flow direction of the liquid return manifold 22 being opposite to that of the liquid supply manifold 21. The liquid supply manifold 21 has a first liquid supply port 211 and a plurality of second liquid supply ports 212. The first liquid supply port 211 and the second liquid supply ports 212 are sequentially spaced along the flow direction of the liquid supply manifold 21. The first liquid supply port 211 is connected to the coolant supply system, and the second liquid supply ports 212 are connected to the corresponding devices to be cooled. Coolant supplied by the coolant supply system enters the liquid supply manifold 21 through the first liquid supply port 211. The coolant entering the liquid supply manifold 21 flows through the second liquid supply ports 212 into the corresponding device to be cooled. The liquid return manifold 22 has a plurality of first liquid return ports 221 and a second liquid return port 222, with the first liquid return ports 221 and the second liquid return port 222 being arranged in sequence along the flow direction of the liquid return manifold 22. Each first liquid return port 221 is connected to a device to be cooled correspondingly, and the second liquid return port 222 is connected to the coolant recovery system. The coolant that has absorbed heat from the device to be cooled enters the liquid return manifold 22 through the first liquid return ports 221 and flows into the coolant recovery system through the second liquid return port 222 of the liquid return manifold 22.

When modifying a conventional data center liquid cooling system, if the manifold assembly of the conventional data center liquid cooling system is the manifold assembly 20 shown in the figures, only the liquid return manifold 22 in manifold assembly 20 requires to be replaced with the liquid return manifold 12 of this embodiment, so as to convert the reverse-return manifold assembly into a direct-return manifold assembly without requiring large-scale reinstallation of the entire liquid cooling system, enabling cost-effective retrofitting with significantly improved implementation efficiency.

The present application provides a data center liquid cooling system including the manifold assembly 10 provided in any of the above embodiments.

Described above are only embodiments of the present application, and it should be pointed out that, for the ordinary technical personnel in the field, improvements may also be made without departing from the premise of the concept of the present application, but these are all within the protection scope of the present application.

What is claimed is:

1. A manifold assembly comprising:
a liquid supply manifold having a first liquid supply port and a plurality of second liquid supply ports, wherein the first liquid supply port and the second liquid supply ports are sequentially spaced apart along a flow direction of the liquid supply manifold, the first liquid supply port is connected to a coolant supply system, and the second liquid supply ports are connected to corresponding devices to be cooled; and
a liquid return manifold comprising a first liquid return tube and a second liquid return tube that are parallel to each other and connected at one end, wherein a flow direction of the first liquid return tube is the same as the flow direction of the liquid supply manifold and opposite to a flow direction of the second liquid return tube; the first liquid return tube is provided with a plurality of first liquid return ports arranged in sequence along the flow direction of the first liquid return tube; the first liquid return ports are connected to the corresponding devices to be cooled, and the second liquid return tube is provided a second liquid return port, which is connected to the coolant recovery system;
wherein lengths of supply and return liquid flow paths of all the devices to be cooled are equal, and the length of each of the supply and return liquid flow path of the device to cooled is a sum of a flow path length between the first liquid supply port and the corresponding second liquid supply port of the device to cooled and a flow path length between the corresponding first liquid return port of the device to cooled and the second liquid return port.

2. The manifold assembly of claim 1, wherein the second liquid return tube is fixed to the first liquid return tube.

3. The manifold assembly of claim 1, wherein the flow direction of the liquid supply manifold is upward.

4. The manifold assembly of claim 3, wherein the manifold assembly further comprises a first exhaust valve and a second exhaust valve, wherein the first exhaust valve is disposed at an upper end of the liquid supply manifold, and the second exhaust valve is disposed at an upper end of the liquid return manifold and is in communication with the first liquid return tube and the second liquid return tube.

5. The manifold assembly of claim 1, wherein a length of the liquid supply manifold, a length of the first liquid return tube, and a length of the second liquid return tube are equal.

6. The manifold assembly of claim 1, wherein a lumen of the liquid supply manifold, a lumen of the first liquid return tube, and a lumen of the second liquid return tube have identical cross-sectional shapes, with equal cross-sectional areas.

7. The manifold assembly of claim 6, wherein the cross-sectional shapes of the lumens of the liquid supply manifold, the first liquid return tube, and the second liquid return tube are square.

8. The manifold assembly of claim 1, wherein the second liquid supply ports are uniformly spaced, the first liquid return ports are uniformly spaced, and a distance between two adjacent second liquid supply ports is equal to a distance between two adjacent first liquid return ports.

9. The manifold assembly of claim 8, wherein the first liquid supply port and the second liquid return port are located at the same height position, and the second liquid supply port and the first liquid return port that are connected to the same device to be cooled are located at the same height position.

10. A data center liquid cooling system, comprising the manifold assembly of claim 1.
